(19) United States
(12) Patent Application Publication
(10) Pub. No.: US 2008/0014696 A1
(43) Pub. Date: Jan. 17, 2008

(54) Trench capacitor and method of manufacturing the same

(76) Inventor: Nan-Hsiung Tsai, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/444,324

(22) Filed: Jun. 1, 2006

(51) Int. Cl. H01L 21/8242; H01L 29/94; H01L 27/108; H01L 29/76; H01L 31/119

(52) U.S. Cl. 438/243; 257/301

(57) ABSTRACT

A trench capacitor and the method of manufacturing the same are provided. A rough polysilicon layer is formed on an inner electrode layer and subsequently mantled by a dielectric layer, and then filled up with an outer electrode layer. The present invention utilizes the characteristic that the rough polysilicon layer has bigger surface area to substantially increase the contact area between the dielectric layer and the inner electrode layer, and make the capacitance of the capacitor increase.

### BACKGROUND OF THE INVENTION

1. Field of the Invention

The present invention relates to a trench capacitor and a method of manufacturing the same. More specifically, the present invention discloses a trench capacitor and a method of manufacturing the trench capacitor with high capacitance by using rough polysilicon to increase the valid contact surface area between an inner metal electrode layer and a dielectric layer.

2. Description of the Prior Art

Each unit cell of a dynamic random access memory (DRAM) matrix comprises a N-type metal-oxide-semiconductor (NMOS) and a capacitor. The NMOS is in charge of the switching of unit cell, while the capacitor is for storing electric charges, which means storing data. Hence, if we could store more electric charges in the capacitor, the difference between signals ‘0’ and ‘1’ will become more apparent, and the speed and accuracy of reading data will be improved thereby. Moreover, more capable electric charges store in the capacitor, less charging frequency the capacitor needs. Since the size of IC has reduced to deep submicron meter, the manufacturing steps of IC have become more complicated, for example the gate oxide in MOSFET has reduced from several hundreds Å to about 40 Å. In this tendency, how to efficiently improve the charging capacity of a reduced-size capacitor has become the most important target in the technique development.

Refer to FIG. 1, which is the drawing of a common trench capacitor, a plurality of trenches 12 are formed on the substrate 10, and are filled up with a silicon inner electrode layer 14, a dielectric layer 16 and a metal or polysilicon layer as an outer electrode 18. But this structure of the capacitor could not provide enough valid surfaces for charge storing, and hence results in low speed and accuracy.

Therefore there is need for improvement in the structure and the manufacturing method of the trench capacitor.

### SUMMARY OF THE INVENTION

To achieve these and other advantages and in order to overcome the disadvantages of the conventional method in accordance with the purpose of the invention as embodied and broadly described herein, the present invention provides an improved structure and manufacturing method of a trench capacitor with high capacitance by using rough polysilicon to increase the valid contact surface area between an inner metal electrode layer and a dielectric layer.

An object of the present invention is to provide a structure and a manufacturing method of a trench capacitor. It utilizes the characteristic that rough polysilicon has bigger surface area to efficiently increase the valid contact surface between the inner metal electrode layer and the dielectric layer, and makes the charge capable stored in the capacitor increase substantially without enlarging the scale of the trench in the layout.

The present invention further provides a structure and a manufacturing method of a trench capacitor, which is able to raise the speed and accuracy in reading stored data of a memory.

The present invention further provides a structure and a manufacturing method of a trench capacitor to substantially decrease the recharging frequency of the capacitor.

To achieve the above objects, the structure of trench capacitor of the present invention comprises a semiconductor substrate having several trenches, an inner electrode layer formed on the trench walls, a rough polysilicon layer on the inner electrode layer, a dielectric layer on the rough polysilicon layer, and an outer electrode layer formed on the dielectric layer and filling up the trench.

And the manufacturing method of trench capacitor of the present invention comprises the following steps: providing a semiconductor substrate having several trenches, forming an inner electrode layer on the trench walls, forming a rough polysilicon layer on the inner electrode layer, then forming a dielectric layer on the rough polysilicon layer, and finally forming an outer electrode layer filling up the trench on the dielectric layer.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a cross sectional view of a conventional structure of a trench capacitor;

FIG. 2 is a cross sectional view of the structure of a trench capacitor according to an embodiment of the present invention;

FIGS. 3(a) to 3(d) illustrate the manufacturing steps of a trench capacitor according to an embodiment of the present invention.

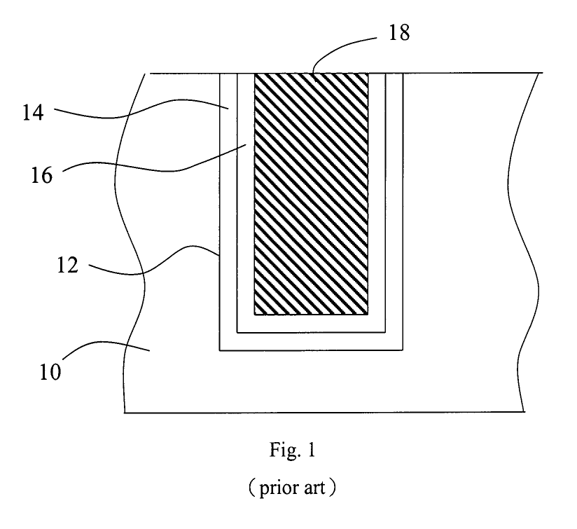

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

The present invention provides a structure and a manufacturing method of a trench capacitor. It utilizes rough polysilicon, which provides larger surface area to increase the charge quantity capable stored in the capacitor and moreover raise the speed and accuracy in reading stored data of the memory.

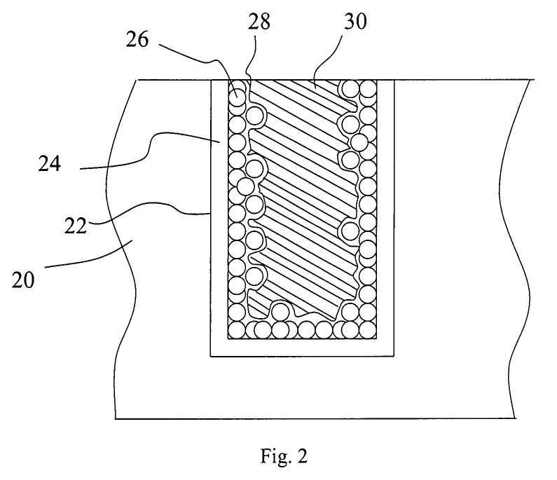

The present invention provides a structure of a trench capacitor, as illustrated in FIG. 2, comprising a semiconductor substrate 20 having a plurality of trenches 22 on it, an inner electrode layer 24 formed on the side walls of the trench, a rough polysilicon layer 26 on the inner electrode layer 24, a dielectric layer 28 on the rough polysilicon layer, and an outer electrode layer 30 formed on the dielectric layer and filling up the trench.

Following is a description of the manufacturing method of the present invention according to the structure shown in FIG. 2. It aims at the manufacturing of the trench capacitor and does not describe the manufacturing of the isolation and gate structures in detail.

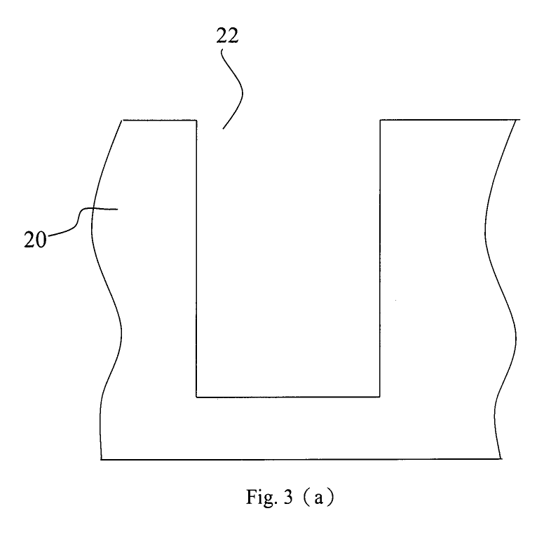

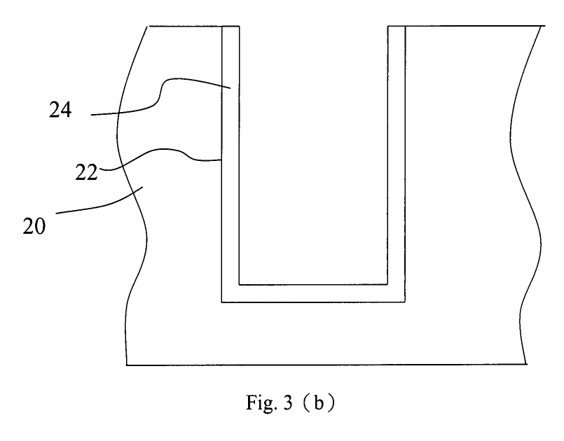

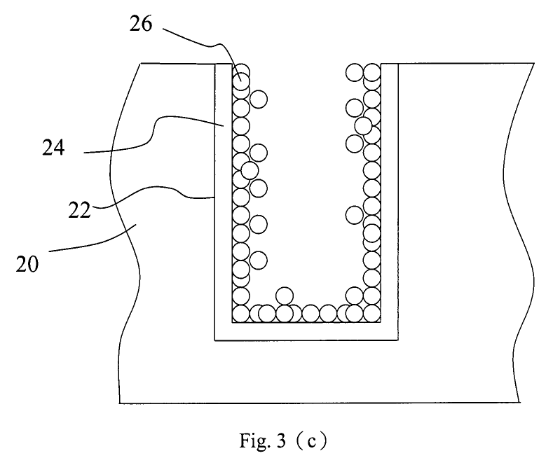

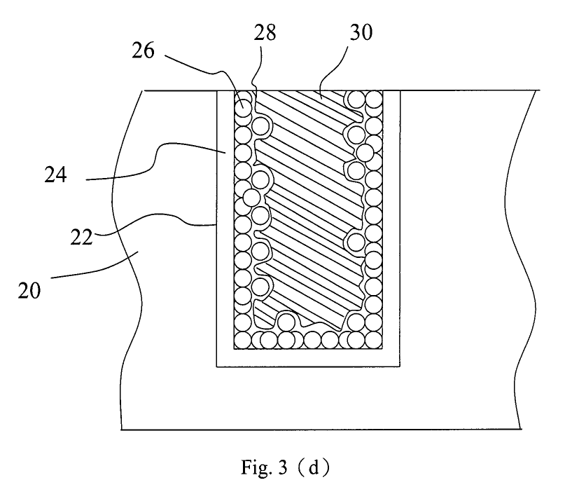

Please refer to FIGS. 3(a) to 3(d), which show cross sectional views of the manufacturing steps according to an embodiment of the present invention. It comprises the following steps:

First, please refer to FIG. 3(a), a plurality of trenches 22 are formed on a semiconductor substrate 20.

Next please refer to FIG. 3(b), where the manufacturing of an inner electrode layer is started. It uses multi-angle implant or thermal diffusion to high dope the walls of the trench 22 formed by etching so that the silicon on the silicon walls of the trench 22 will transform into storage node electrode which can conduct electricity and is regarded as an inner electrode layer 24. Then using chemical vapor deposition (CVD) to deposit a rough polysilicon layer 26 on the inner electrode layer as illustrated in FIG. 3(c), wherein the rough polysilicon layer is deposited at the temperature 570° C.-590° C.

Please refer to FIG. 3(d), a dielectric layer 28 is formed on the rough polysilicon layer 26. The dielectric layer 28 can be composed of Si₃N₄, a collocation of a silicon nitride layer and a SiO₂ layer, or other dielectric materials with high dielectric constant. When the dielectric layer is composed of Si₃N₄, in order to maintain the dielectric constant of the dielectric layer, HF is first used to etch the rough polysilicon layer for removing the oxide on the surface. The etching step will slightly rough the surface of the rough polysilicon layer. Then the wafer is sent into a furnace to deposit Si₃N₄ by CVD in the vacuum environment, or remove SiO₂ directly by the chemical reaction of hydrogen or ammonia before the deposition of Si₃N₄ to achieve the object of raising dielectric constant and the quality of the capacitor.

Subsequently an outer electrode layer 30 is deposited on the dielectric layer 28 and fills up the trench 22. The outer electrode layer 30 can be composed of polysilicon or metal. Then chemical mechanical polishing (CMP) is used to remove the redundant part of the outer electrode layer outside the trench. And the manufacturing steps of the high capacity trench capacitor have been completed.

To conclude, the present invention discloses a structure and a manufacturing method of a trench capacitor. It utilizes the rough polysilicon having bigger surface area to substantially increase the valid area for electric charge storing, then raise the speed and accuracy of a memory, and reduce the recharging frequency of the capacitor.

It will be apparent to those skilled in the art that various modifications and variations can be made to the present invention without departing from the scope or spirit of the invention. In view of the foregoing, it is intended that the present invention cover modifications and variations of this invention provided they fall within the scope of the invention and its equivalent.

What is claimed is:

1. A manufacturing method of a trench capacitor comprising:
providing a semiconductor substrate which has a plurality of trenches;
forming an inner electrode layer in the trenches;
forming a rough polysilicon layer on the inner electrode layer;
forming a dielectric layer on the rough polysilicon layer; and
forming an outer electrode layer on the dielectric layer to fill up the trenches.

2. The manufacturing method of a trench capacitor of claim 1, wherein the inner electrode layer is formed by high doping into the walls of the trenches.

3. The manufacturing method of a trench capacitor of claim 1, wherein the dielectric layer comprises a silicon nitride layer and a SiO₂ layer.

4. The manufacturing method of a trench capacitor of claim 1, wherein the dielectric layer is composed of SiO₂.

5. The manufacturing method of a trench capacitor of claim 1, wherein the rough polysilicon layer is formed by chemical deposition.

6. The manufacturing method of a trench capacitor of claim 1, wherein the outer electrode layer is a metal layer or a polysilicon layer.

7. A structure of a trench capacitor comprising:
a semiconductor substrate having a plurality of trenches thereon;
an inner electrode layer formed on the walls of the trenches;
a rough polysilicon layer formed on the inner electrode layer;
a dielectric layer formed on the rough polysilicon layer; and
an outer electrode layer formed on the dielectric layer.

8. The structure of a trench capacitor of claim 7, wherein the inner electrode layer is formed by high doping the walls of the trenches.

9. The structure of a trench capacitor of claim 7, wherein the dielectric layer comprises a silicon nitride layer and a SiO₂ layer.

10. The structure of a trench capacitor of claim 7, wherein the dielectric layer is composed of SiO₂.

11. The structure of a trench capacitor of claim 7, wherein the rough polysilicon layer is formed by chemical deposition.

12. The structure of a trench capacitor of claim 7, wherein the outer electrode layer is a metal layer or a polysilicon layer.
